(19) United States
(12) Patent Application Publication
(10) Pub. No.: US 2026/0293606 A1
(43) Pub. Date: Sep. 24, 2026

(54) SUBSTRATE CLAMPING DEVICE AND SUBSTRATE TREATMENT APPRATUS INCLUDING THE SAME

(71) Applicant: PSK Holdings Inc., Hwaseong-si, Gyeonggi-do (KR)

(72) Inventor: Junyoung NA, Pyeongtaek-si, Gyeonggi-do (KR)

(73) Assignee: PSK Holdings Inc., Hwaseong-si, Gyeonggi-do (KR)

(21) Appl. No.: 19/475,399

(22) PCT Filed: Apr. 16, 2024
(86) PCT No.: PCT/KR2024/095743

§ 371 Date: Oct. 14, 2025

(30) Foreign Application Priority Data
Apr. 18, 2023 (KR) 10-2023-0050420

(51) Int. Cl. H10P 72/76

(52) U.S. Cl. CPC H10P 72/7606; H10P 72/7624

(57) ABSTRACT

The present invention relates to a substrate clamping device and a substrate treatment apparatus including the same, and more particularly, to a substrate clamping device that distributes and applies a pressing force for preventing warpage of a substrate and a substrate treatment apparatus including the same.

According to an embodiment, it is possible to provide a substrate clamping device including: a supporting unit configured to support a substrate; a clamp ring that applies a load to a peripheral region of the substrate to prevent warpage of the substrate in a treatment process of the substrate; a driving unit that lifts the clamp ring; and a damping unit that distributes the load applied to the substrate by the clamp ring by lowering of the driving unit, wherein the damping unit includes: a clamp guide coupled to the driving unit to be lifted by the driving unit and having a damping groove at an upper end portion; a damping member coupled to the clamp guide to be operated integrally and provided inside the damping groove; and a damping guide inserted into the damping groove to be provided under the damping member and configured to press the clamp ring by distributing a pressing force of the damping member when the driving unit is driven to lower.

### TECHNICAL FIELD

The present invention relates to a substrate clamping device and a substrate treatment apparatus including the same, and more particularly, to a substrate clamping device that distributes a pressing force for preventing warpage of a substrate and a substrate treatment apparatus including the same.

The present invention was derived from research conducted as part of the Small and Medium Enterprise Technology Innovation Development (Materials, Components, Equipment, Account) of the Ministry of SMEs and Startups (Project Identification No.: 1425167087, Sub-Project No.: S3300781, Research Project Title: Plasma Treatment Device for Fan-Out Semiconductor Packaging, Institute of Organization: Korea Technology and Information Promotion Agency for SMEs, Research Period: Jun. 24, 2022 to Dec. 31, 2022).

### BACKGROUND ART

A semiconductor integrated circuit is generally a very small and thin silicon chip but it is composed of various electronic components, and a single semiconductor chip is produced through various manufacturing processes such as a photo process, an etching process, a deposition process, a reflow process, and a packaging process. As various materials are deposited on a semiconductor substrate such as a wafer, a warpage phenomenon may occur on the semiconductor substrate due to factors such as different thermal expansion coefficients. Such a warpage phenomenon may be shown differently depending on a material (e.g., silicon, glass, etc.) of the wafer.

When plasma treatment is performed in a state in which the warpage has occurred on the wafer in this way, local plasma may occur on a lower surface of the wafer, thereby causing damage to the wafer and components. In order to prevent this, a clamp ring that is referred to as a window clamp may be disposed on a periphery of the wafer and a clamp load is applied to the periphery of the wafer by the clamp ring so as to prevent the warpage of the wafer. The method of disposing the clamp ring on the periphery of the wafer has problems that it is difficult to control a pressing force applied to the wafer, an operation of disposing the clamp ring on the wafer needs to be performed outside a chamber before loading in the chamber, and a transfer process is limited to prevent the clamp ring on the wafer from being misaligned.

A method of pressing the periphery of the wafer by providing a device that drives the clamp ring to be lifted inside the chamber has an advantage that it is possible to control the pressing force applied to the wafer, the operation of disposing the clamp ring does not need to be performed outside the chamber, and restriction on the wafer transfer process may be reduced. However, in a case of a conventional clamp ring lifting device, there is a disadvantage in that the clamp ring applies a direct load to the periphery of the wafer, thereby causing damage to the wafer.

### DISCLOSURE

### Technical Problem

The present invention is directed to providing a substrate clamping device that prevents warpage that may be caused by differences in thermal expansion coefficients and thermal stresses between materials in a substrate treatment process by providing a pressing force to a substrate, and a substrate treatment apparatus including the same.

In addition, the present invention is directed to providing a substrate clamping device that distributes a pressing force provided to a substrate through a damping unit to reduce a risk of a damage to the substrate and increase efficiency of a substrate treatment process, and a substrate treatment apparatus including the same.

In addition, the present invention is directed to providing a substrate clamping device that further distributes a pressing force provided to a substrate by including a spring to further reduce a risk of a damage to the substrate and increase efficiency of a substrate treatment process, and a substrate treatment apparatus including the same.

In addition, the present invention is directed to providing a substrate clamping device that may stably provide a pressing force to a substrate by providing a space for disposing the substrate between a guide ring and a clamp ring, and a substrate treatment apparatus including the same.

In addition, the present invention is directed to providing a substrate clamping device that is easy to maintain and economical as a damping member, a clamp guide, and a clamp ring may be mutually coupled and separated, and a substrate treatment apparatus including the same.

In addition, the present invention is directed to providing a substrate clamping device that controls a driving unit according to a measured pressing force to apply an appropriate pressing force according to a physical property value of a substrate, and a substrate treatment apparatus including the same.

### Technical Solution

According to an embodiment, it is possible to provide a substrate clamping device including: a supporting unit configured to support a substrate; a clamp ring that applies a load to a peripheral region of the substrate to prevent warpage of the substrate in a treatment process of the substrate; a driving unit that lifts the clamp ring; and a damping unit that distributes the load applied to the substrate by the clamp ring by lowering of the driving unit, wherein the damping unit includes: a clamp guide coupled to the driving unit to be lifted by the driving unit and having a damping groove at an upper end portion; a damping member coupled to the clamp guide to be operated integrally and provided inside the damping groove; and a damping guide inserted into the damping groove to be provided under the damping member and configured to press the clamp ring by distributing a pressing force of the damping member when the driving unit is driven to lower.

In addition, it is possible to provide the substrate clamping device wherein the damping guide includes a sliding portion with a first inner diameter and a locking portion formed with a second inner diameter that is greater than the first inner diameter to form a step with the sliding portion.

In addition, it is possible to provide the substrate clamping device wherein the damping member includes: a damping shaft which has a length in a vertical direction and of which a lower end fixedly coupled to the clamp guide; and a pressing main body that is coupled to an upper end of the damping shaft, slides along an inner circumferential surface of the damping guide, and has a step portion that is interlocked with the locking portion formed therein.

In addition, it is possible to provide the substrate clamping device wherein the damping member further includes a spring disposed between the pressing main body and a lower surface of the damping groove to buffer lifting of the pressing main body.

In addition, it is possible to provide the substrate clamping device wherein the spring is provided to surround an outer circumferential surface of the damping shaft.

In addition, it is possible to provide the substrate clamping device wherein the supporting unit includes a guide ring on which a guide protrusion that is spaced apart from an inner circumferential surface and protrudes from an upper surface is formed, and the clamp ring further includes a guide groove that surface-contacts an upper surface of the guide protrusion.

In addition, it is possible to provide the substrate clamping device wherein the clamp ring is formed so that a vertical thickness of a first region close to the inner circumferential surface is smaller than a vertical thickness of a second region close to an outer circumferential surface, so that the substrate is disposed between the guide ring and the clamp ring.

In addition, it is possible to provide the substrate clamping device wherein the vertical thickness of the first region is smaller by a thickness of the substrate than the vertical thickness of the second region.

In addition, it is possible to provide the substrate clamping device wherein the driving unit includes at least three driving frames and an actuator for inserting and withdrawing the driving frames.

In addition, it is possible to provide the substrate clamping device wherein the clamp ring includes a clamp ring main body with a circular ring shape and a connection piece that is formed to protrude in a radial direction from an outer circumferential surface of the clamp ring main body, and an insertion hole into which the damping guide is inserted is provided in the connection piece.

In addition, it is possible to provide the substrate clamping device wherein the connection piece is disposed between an upper surface of the clamp guide and the locking portion of the damping guide so that the clamp ring applies the distributed load to the substrate.

In addition, it is possible to provide the substrate clamping device wherein the clamp guide includes a detachable groove with a screw portion under the damping groove, and a screw coupling portion that is screw-coupled to the screw portion is provided on the outer circumferential surface of the damping shaft so that the damping member may be detached from the clamp guide.

In addition, it is possible to provide the substrate clamping device wherein the damping member is made of an elastic material.

In addition, it is possible to provide the substrate clamping device further including: a measuring unit that measures a pressing force pressed by the driving unit; and a control unit that controls a driving force of the driving unit according to the pressing force measured by the measuring unit.

According to an embodiment, it is possible to provide a substrate treatment apparatus including: the substrate clamping device of claim 1; and a treatment unit that performs a substrate treatment for the substrate that is supported on the supporting unit.

### Advantageous Effects

According to an embodiment of the present invention, it is possible to provide a substrate clamping device that prevents warpage that may be caused by differences in thermal expansion coefficients and thermal stresses between materials in a substrate treatment process by providing a pressing force to a substrate, and a substrate treatment apparatus including the same.

According to the embodiment of the present invention, it is possible to provide a substrate clamping device that distributes a pressing force provided to a substrate through a damping unit to reduce a risk of a damage to the substrate and increase efficiency of a substrate treatment process, and a substrate treatment apparatus including the same.

In addition, according to the embodiment of the present invention, it is possible to provide a substrate clamping device that further distributes a pressing force provided to a substrate by including a spring to further reduce a risk of a damage to the substrate and increase efficiency of a substrate treatment process, and a substrate treatment apparatus including the same.

In addition, according to the embodiment of the present invention, it is possible to provide a substrate clamping device that may stably provide a pressing force to a substrate by providing a space for disposing the substrate between a guide ring and a clamp ring, and a substrate treatment apparatus including the same.

In addition, according to an embodiment of the present invention, it is possible to provide a substrate clamping device that is easy to maintain and economical as a damping member, a clamp guide, and a clamp ring may be mutually coupled and separated, and a substrate treatment apparatus including the same.

In addition, according to an embodiment of the present invention, it is possible to provide a substrate clamping device that controls a driving unit according to a measured pressing force to apply an appropriate pressing force according to a physical property value of a substrate, and a substrate treatment apparatus including the same.

Meanwhile, effects that can be obtained from the present invention are not limited to the above-mentioned effects, and other effects that are not mentioned can be clearly understood by those having ordinary skill in the technical field to which the present invention belongs from the description below.

### DESCRIPTION OF DRAWINGS

FIG. 1 is a perspective view of a substrate clamping device according to an embodiment of the present invention.

FIG. 2 is a cross-sectional view of the substrate clamping device according to the embodiment of the present invention.

FIG. 3 is an enlarged view of “B” portion shown in FIG. 2.

FIG. 4 is a cross-sectional view of the substrate clamping device and a substrate treatment apparatus including the same according to the embodiment of the present invention.

FIG. 5 is a cross-sectional view showing a first embodiment of “C” portion shown in FIG. 4.

FIG. 6 is a cross-sectional view showing a second embodiment of the “C” portion shown in FIG. 4.

FIG. 7 is a cross-sectional view showing a third embodiment of the “C” portion shown in FIG. 4.

FIG. 8 is an exemplary view of a control unit according to the embodiment of the present invention.

### MODES OF THE INVENTION

Hereinafter, embodiments of the present invention will be described in more detail with reference to the attached drawings. The embodiments of the present invention can be modified in various forms, and the scope of the present invention should not be construed as being limited to the embodiments below. The embodiments are provided to more completely describe the present invention to those having ordinary skill in the art. Accordingly, shapes of elements in the drawing are exaggerated to emphasize a clearer description. In order to clearly solve the problems to be solved by the present invention, the composition of the present invention will be described in detail with reference to the attached drawings based on a preferred embodiment of the present invention, and when assigning reference numerals to components in the drawings, the same reference numerals are assigned to the same components even if they are in different drawings, and it is made clear in advance that components in other drawings may be cited when necessary when describing the drawings.

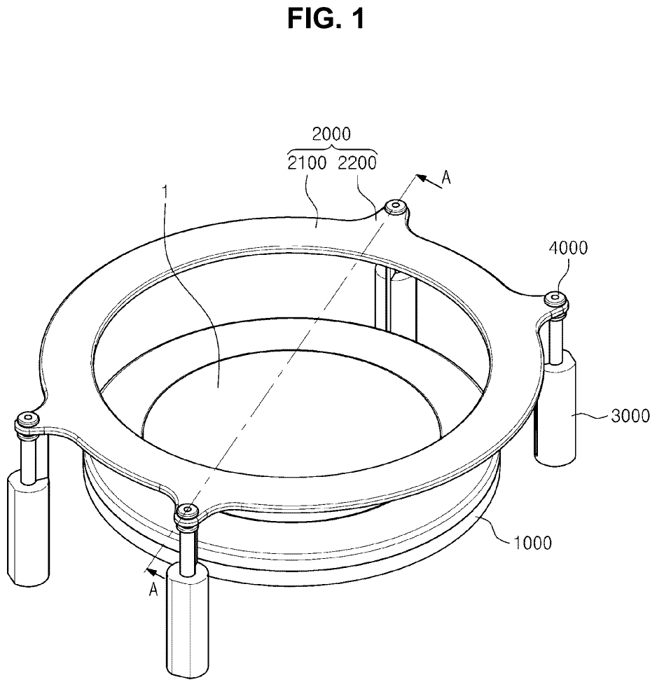

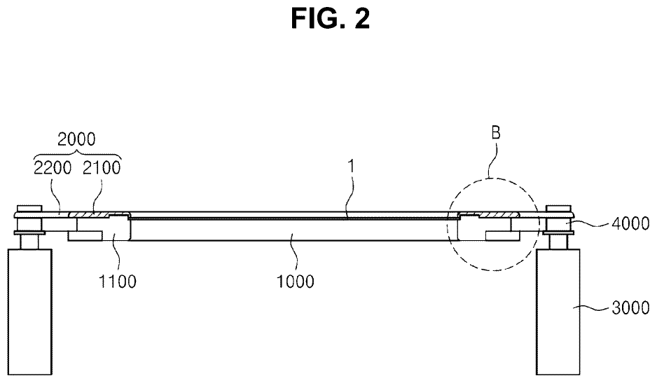

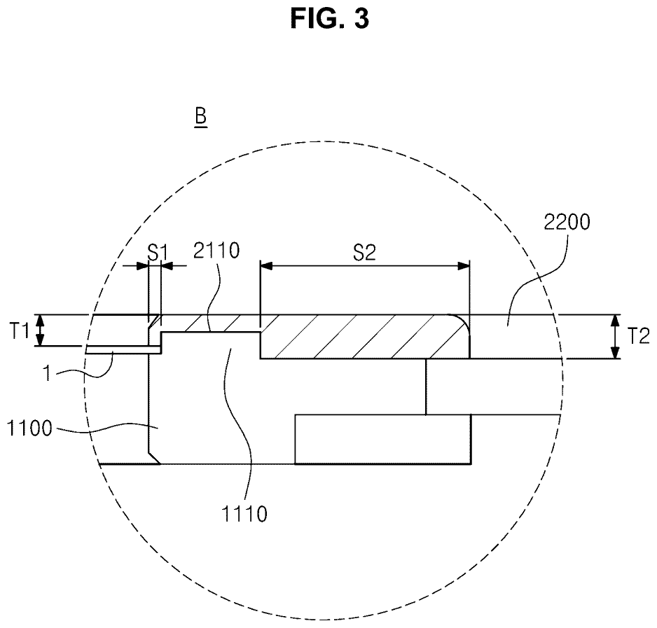

FIG. 1 is a perspective view of a substrate clamping device according to an embodiment of the present invention. FIG. 2 is a cross-sectional view of the substrate clamping device according to the embodiment of the present invention. FIG. 3 is an enlarged view of “B” portion shown in FIG. 2. Referring to FIG. 1 to FIG. 3, the substrate clamping device may prevent an occurrence of warpage of a substrate 1 by pressing a peripheral region of the substrate 1. The substrate 1 may be provided as a semiconductor wafer, a mask, a glass substrate, or a liquid crystal display (LCD) panel, but it is not limited thereto.

A substrate clamping device 10 according to an embodiment of the present invention includes a supporting unit 1000, a clamp ring 2000, a driving unit 3000, and a damping unit 4000.

The supporting unit 1000 may be provided to support the substrate 1. Although not shown, the supporting unit 1000 may be provided with a supporting chuck and a plurality of lift pins. The plurality of lift pins may lift the substrate 1 and the supporting chuck may support the lowered substrate 1.

In addition, the supporting unit 1000 may include a guide ring 1100. The guide ring 1100 may have a circular ring shape and provide a guide for seating the substrate 1. Specifically, the guide ring 1100 may include a guide protrusion 1110, and the guide protrusion 1110 may be formed to protrude from an upper surface of the guide ring. Here, a vertical direction is expressed based on FIG. 2 for convenience of description. The guide protrusion 1110 may be provided in plural at regular intervals (angles) in a peripheral direction of the guide ring 1100.

The substrate 1 may be seated in the guide ring 1100. Specifically, a peripheral region of the substrate 1 may be seated in a first region S1 that is a region close to an inner circumferential surface of the guide ring 1100 based on the guide protrusion 1110. Thus, the substrate 1 may be stably supported in a predetermined position, and the peripheral region of the substrate 1 may be pressed with a uniform pressing force in the peripheral direction by the clamp ring 2000.

The clamp ring 2000 may apply a load to the peripheral region of the substrate 1 to prevent the warpage of the substrate 1 in a treatment process of the substrate. The clamp ring 2000 may include a clamp ring main body 2100 and a connection piece 2200.

The clamp ring main body 2100 may have a circular ring shape and include a guide groove 2110 on a lower surface thereof. The guide groove 2110 may be formed with a shape corresponding to the guide protrusion 1110 and may be formed to correspond to surface-contact an upper surface of the guide protrusion 1110. Thus, the clamp ring 2000 may be interlocked with the guide ring 1100 to suppress a positional misalignment of the clamp ring 2000, thereby improving efficiency of the substrate treatment process.

In addition, the clamp ring main body 2100 may be formed so that a vertical thickness T1 of the first region S1 close to the inner circumferential surface based on the guide protrusion 1110 is smaller than a vertical thickness T2 of the second region S2 close to the outer circumferential surface so that the substrate 1 may be disposed between the guide ring 1100 and the clamp ring 2000.

For example, the vertical thickness T1 in the first region S1 of the clamp ring 2000 may be formed to be smaller by a thickness of the substrate 1 than the vertical thickness T2 in the second region S2. Accordingly, the peripheral region of the substrate 1 may be precisely seated in the first region S1 of the guide ring 1100 to be pressed by the clamp ring without any positional misalignment.

The connection piece 2200 may be formed to protrude in a radial direction from the outer circumferential surface of the clamp ring main body 2100 and an insertion hole may be provided in the connection piece 2200. The connection piece 2200 may be provided in the same number as the damping unit 4000. In the shown embodiment, four connection pieces 2200 are provided on the outer circumferential surface of the clamp ring main body 2100, but a number of the connection pieces 2200 may be changed variously. The damping unit 4000 may be inserted into the insertion hole so that the clamp ring 2000 distributes the pressing force provided to the substrate 1. A detailed description thereof will be described later.

The driving unit 3000 may lift the clamp ring 2000. Specifically, the driving unit 3000 may include at least three driving frames 3100 and an actuator 3200, and the actuator 3200 may insert and withdraw the driving frame 3100.

When the driving frame 3100 is inserted by the actuator 3200, the clamp ring 2000 may be lowered so that a lower surface of an inner diameter portion of the clamp ring 2000 is in contact with an upper surface of the substrate 1, and when the driving frame 3100 is withdrawn by the actuator 3200, the clamp ring 2000 may be lifted so that the lower surface of the inner diameter portion of the clamp ring 2000 is spaced apart from the upper surface of the substrate 1 and the guide ring 1100.

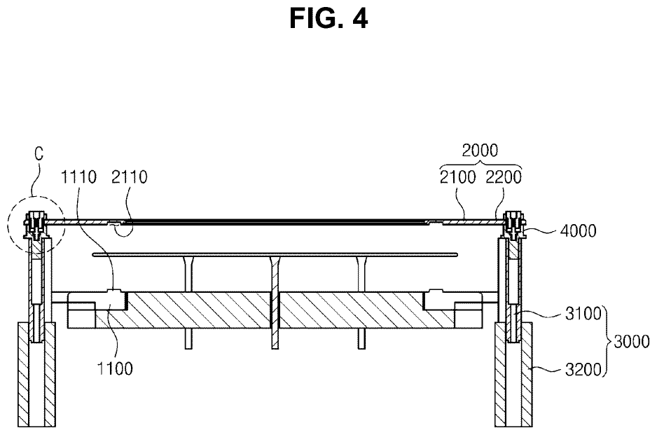

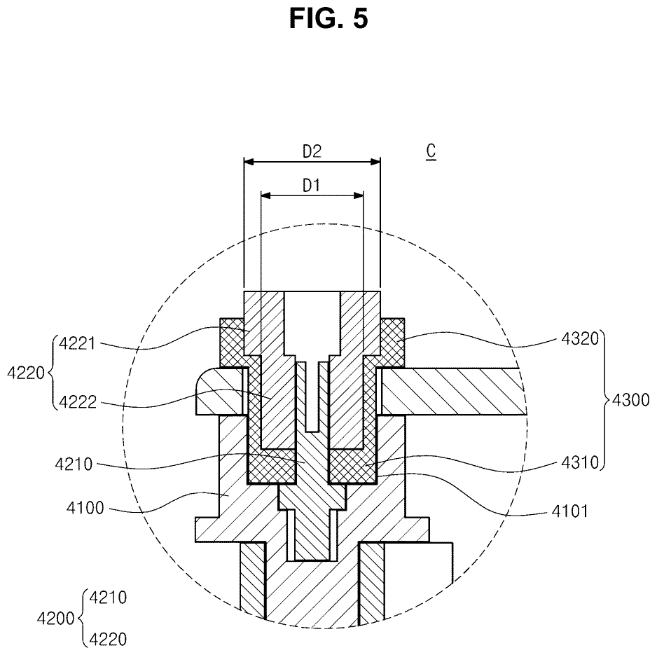

FIG. 4 is a cross-sectional view of a substrate treatment apparatus including the substrate clamping device according to the embodiment of the present invention. FIG. 5 is a cross-sectional view showing a first embodiment of “C” portion shown in FIG. 4.

Referring to FIG. 1 to FIG. 5 together, a damping unit 4000 according to the first embodiment of the present invention may distribute the load applied to the substrate 1 by the clamp ring 2000 by lowering of the driving unit 3000. The damping unit 4000 may include a clamp guide 4100, a damping member 4200, and a damping guide 4300.

The clamp guide 4100 may be coupled to the driving unit 3000 to be lifted by the driving unit 3000. When the clamp guide 4100 is lifted by the driving unit 3000, a lower surface of the clamp ring 2000 is supported and lifted by the clamp guide 4100, and when the clamp guide 4100 is lowered, the clamp ring 2000 may be seated on the clamp guide 4100.

The clamp guide 4100 may have a damping groove 4101 formed at an upper end portion thereof. The damping groove 4101 may have a shape of which an upper surface is open.

The damping member 4200 may be coupled to the clamp guide 4100 to be operated integrally and may be provided inside the damping groove 4101. The damping member 4200 may be made of an elastic material or an inelastic material. When the damping member 4200 is made of the elastic material, the load applied to the substrate 1 may be distributed by buffering of the damping member 4200.

The damping member 4200 may include a damping shaft 4210 and a pressing main body 4220. The damping shaft 4210 may have a length in the vertical direction and a lower end thereof may be fixedly coupled to the clamp guide 4100. The pressing main body 4220 may be coupled to an upper end of the damping shaft 4210 and may slide along an inner circumferential surface of the damping guide 4300.

Specifically, the pressing main body 4220 may include a step portion 4221 and a pressing body 4222. A detailed description thereof will be described later along with the damping guide 4300.

The damping guide 4300 may be inserted into the damping groove 4101 to be provided under the damping member 4200 and may be configured to press the clamp ring 2000 by distributing a pressing force of the damping member 4200 when the driving unit 3000 is driven to lower.

Specifically, the damping guide 4300 may include a sliding portion 4310 and a locking portion 4320. The sliding portion 4310 may be formed to have a cylindrical shape of which an upper portion is open and to have a first inner diameter D1. In this case, the first inner diameter D1 may be designed with the same value as a diameter of the damping groove 4101. Thus, the sliding portion 4310 may be inserted into the damping groove 4101 and may be lifted together with the clamp guide 4100 by the lifting of the clamp guide 4100.

In addition, a communication hole may be formed on a lower surface of the sliding portion 4310 so that the damping shaft 4210 may be inserted.

The locking portion 4320 may be formed above the sliding portion 4310 and may be formed with a second inner diameter D2 greater than the first inner diameter D1 to form a step with the sliding portion 4310. The locking portion 4320 may be formed to be interlocked with the step portion 4221 of the pressing main body 4220, thereby pressing the damping guide 4300 when the clamp guide 4100 fixedly coupled to the damping member 4200 is lowered.

In other words, when the clamp guide 4100 is lowered, the damping member 4200 may be driven to lower together, and the damping guide 4300 may be disposed between the clamp guide 4100 and the pressing main body 4220 and interlocked with the step portion 4221 of the pressing main body 4220 to be driven to lower together.

In this case, the connection piece 2200 may be disposed between the clamp guide 4100 and the locking portion 4320 of the damping guide 4300, and the damping guide 4300 may be inserted into the insertion hole provided in the connection piece 2200. Thus, the load applied to the substrate 1 by the clamp ring 2000 by the lowering of the driving unit 3000 may be distributed by the damping unit 4000.

In addition, an outer circumferential surface of the damping guide 4300 may have a shape corresponding to the inner circumferential surface of the clamp guide 4100, so that when the clamp guide 4100 is lowered, the damping guide 4300 may be stably lowered while sliding along the outer circumferential surface of the clamp guide 4100.

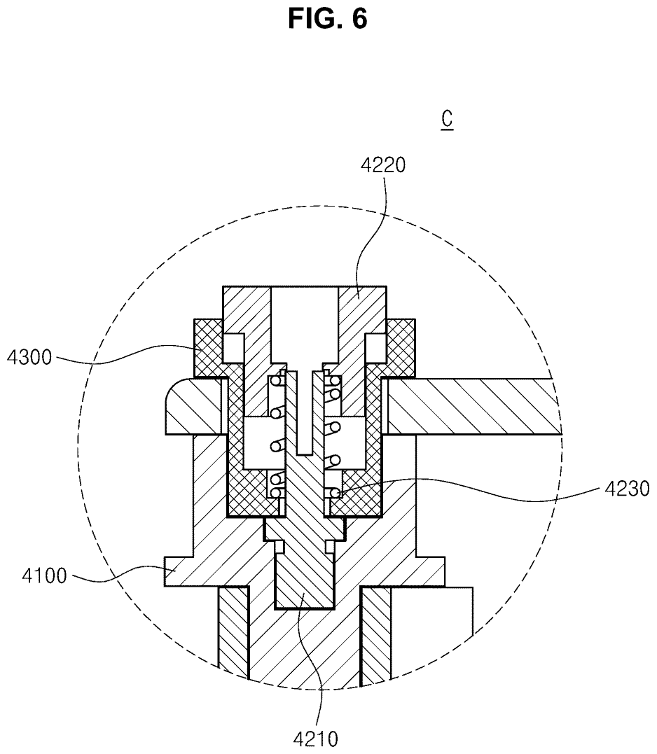

FIG. 6 is a cross-sectional view showing a second embodiment of the “C” portion shown in FIG. 4. Referring to FIG. 1 to FIG. 4 and FIG. 6 together, a damping member 4200 according to the second embodiment of the present invention has a different configuration of a spring 4230 compared to the damping member 4200 according to the first embodiment of the present invention shown in FIG. 5, and therefore, only the different configuration will be described below, and a detailed description of redundant reference numerals for the same configuration will be omitted.

The damping member 4200 may further include the spring 4230. The spring 4230 may be disposed between the pressing main body 4220 and a lower surface of the damping groove 4101 to buffer lifting of the pressing main body 4220.

For example, when the damping guide 4300 applies a load to the substrate 1 by lowering of the damping member 4200, the spring 4230 may be compressed to buffer the load applied to the substrate 1.

In addition, the spring 4230 may be provided to surround an outer circumferential surface of the damping shaft 4210, but it is not necessarily limited thereto.

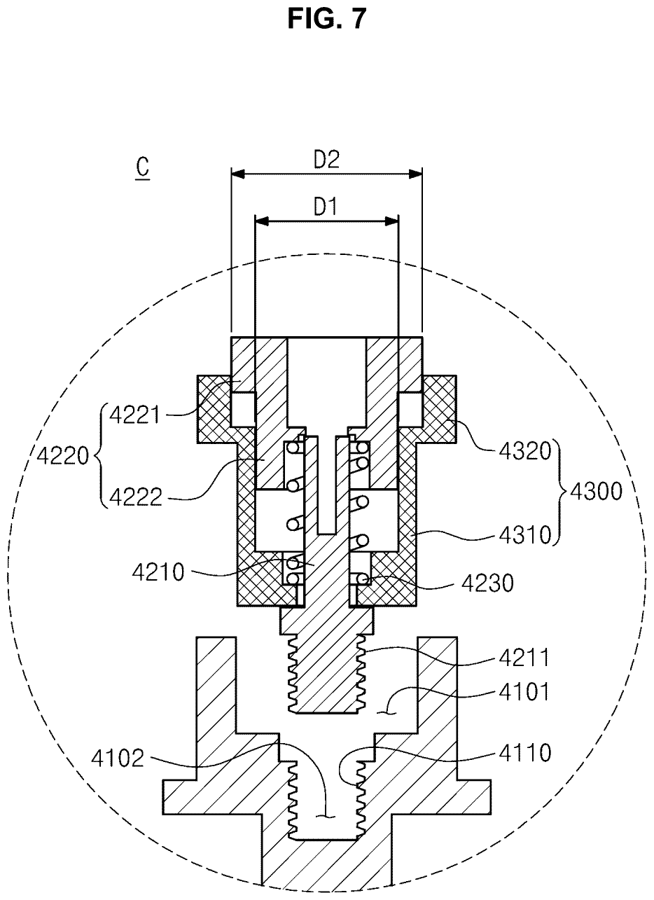

FIG. 7 is a cross-sectional view showing a third embodiment of the “C” portion shown in FIG. 4. Referring to FIG. 1 to FIG. 7 together, a damping unit 4000 according to the third embodiment of the present invention has different configurations of the clamp guide 4100 and the damping member 4200 compared to the damping unit 4000 according to the second embodiment of the present invention shown in FIG. 6 and therefore, only the different configurations will be described below, and a detailed description of redundant reference numerals for the same configuration will be omitted.

The clamp guide 4100 may include a detachable groove 4102 under the damping groove 4101, and the detachable groove may include a screw portion 4110 on an inner circumferential surface thereof. A screw coupling portion 4211 that is screw-coupled to the screw portion 4110 may be provided on the outer circumferential surface of the damping shaft 4210. Thus, the damping member 4200 may be detached from the clamp guide 4100.

For example, the clamp ring 2000 may be disposed above the clamp guide 4100, but the insertion hole formed in the connection piece 2200 and the damping groove 4101 of the clamp guide 4100 may be disposed so as to communicate with each other, the damping member 4200 and the damping guide 4300 may be provided inside the damping groove 4101, but the damping guide 4300 may be inserted into the damping groove 4101 to slide.

In this case, the screw portion 4110 formed on the outer circumferential surface of the damping shaft 4210 of the damping guide 4300 may be screw-coupled to the screw coupling portion 4211 formed in the detachable groove 4102 provided under the damping groove 4101.

Thus, the clamp ring 2000, the clamp guide 4100, and the damping member 4200 may be mutually coupled and separated, thereby easily maintaining.

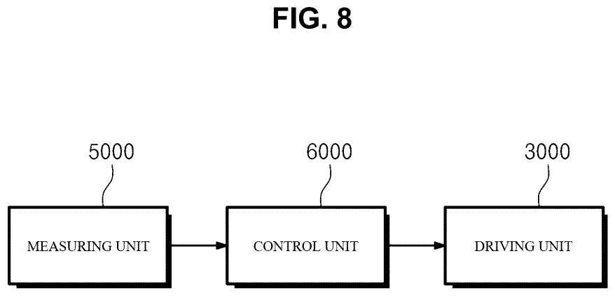

FIG. 8 is an exemplary view of a control unit according to the embodiment of the present invention. Referring to FIG. 1 to FIG. 8 together, the substrate clamping device 10 may further include a measuring unit 5000 and a control unit 6000.

The measuring unit 5000 may measure a pressing force pressed by the driving unit 3000. The measuring unit 5000 may be a pressure sensor that directly measures the pressing force applied to the substrate 1, and for example, as used in a touch panel or the like, when the pressing force acts, a pressed position and the pressing force may be detected.

The control unit 6000 may control a driving force of the driving unit 3000 according to the pressing force measured by the measuring unit 5000. When the measured pressing force is greater than a preset value, the driving frame 3100 may be withdrawn, and when the measured pressing force is smaller than the preset value, the driving frame 3100 may be inserted. In this case, the preset value is a value of the pressing force required to prevent warpage from occurring in the substrate 1 during the substrate treatment process according to a physical property value of the substrate 1 and may be determined by a corresponding table and the like.

In addition, a substrate treatment apparatus 100 including the substrate clamping device according to the embodiment of the present invention may prevent an occurrence of the warpage of the substrate in the substrate treatment process such as a plasma process, a package process, a reflow process, an etching process, a deposition process, a photo process, or a heat treatment process.

Specifically, the substrate treatment apparatus 100 including the substrate clamping device may further include a treatment unit (not shown). The treatment unit may perform a substrate treatment for the substrate 1 supported on the supporting unit 1000. Here, the treatment unit may perform the photo process, the etching process, the deposition process, the reflow process, the package process, or the like.

The above detailed description is illustrative of the present invention. Furthermore, the above description shows and describes the preferred embodiment of the present invention, and the present invention may be used in various other combinations, changes, and environments. That is, changes or modifications are possible within the scope of the idea of the invention disclosed herein, the scope equivalent to the described disclosure, and/or the scope of technology or knowledge in the art. The described embodiments describe the best possible state for implementing the technical idea of the present invention, and various changes required for specific application fields and uses of the present invention are also possible. Accordingly, the above detailed description of the invention is not intended to limit the invention to the disclosed embodiments. In addition, the appended claims should be construed to include other embodiments.

1. A substrate clamping device comprising:
a supporting unit configured to support a substrate;
a clamp ring that applies a load to a peripheral region of the substrate to prevent warpage of the substrate in a treatment process of the substrate;
a driving unit that lifts the clamp ring; and
a damping unit that distributes the load applied to the substrate by the clamp ring by lowering of the driving unit,
wherein the damping unit includes:
a clamp guide coupled to the driving unit to be lifted by the driving unit and having a damping groove at an upper end portion;
a damping member coupled to the clamp guide to be operated integrally and provided inside the damping groove; and
a damping guide inserted into the damping groove to be provided under the damping member and configured to press the clamp ring by distributing a pressing force of the damping member when the driving unit is driven to lower.

2. The substrate clamping device of claim 1, wherein the damping guide includes a sliding portion with a first inner diameter and a locking portion formed with a second inner diameter that is greater than the first inner diameter to form a step with the sliding portion.

3. The substrate clamping device of claim 2, wherein the damping member includes:
a damping shaft which has a length in a vertical direction and of which a lower end fixedly coupled to the clamp guide; and
a pressing main body that is coupled to an upper end of the damping shaft, slides along an inner circumferential surface of the damping guide, and has a step portion that is interlocked with the locking portion formed therein.

4. The substrate clamping device of claim 3, wherein the damping member further includes a spring disposed between the pressing main body and a lower surface of the damping groove to buffer lifting of the pressing main body.

5. The substrate clamping device of claim 4, wherein the spring is provided to surround an outer circumferential surface of the damping shaft.

6. The substrate clamping device of claim 1, wherein the supporting unit includes a guide ring on which a guide protrusion that is spaced apart from an inner circumferential surface and protrudes from an upper surface is formed, and
the clamp ring further includes a guide groove that surface-contacts an upper surface of the guide protrusion.

7. The substrate clamping device of claim 6, wherein the clamp ring is formed so that a vertical thickness of a first region close to the inner circumferential surface is smaller than a vertical thickness of a second region close to an outer circumferential surface, so that the substrate is disposed between the guide ring and the clamp ring.

8. The substrate clamping device of claim 7, wherein the vertical thickness of the first region is smaller by a thickness of the substrate than the vertical thickness of the second region.

9. The substrate clamping device of claim 1, wherein the driving unit includes at least three driving frames and an actuator for inserting and withdrawing the driving frames.

10. The substrate clamping device of claim 2, wherein the clamp ring includes a clamp ring main body with a circular ring shape and a connection piece that is formed to protrude in a radial direction from an outer circumferential surface of the clamp ring main body, and
an insertion hole into which the damping guide is inserted is provided in the connection piece.

11. The substrate clamping device of claim 10, wherein the connection piece is disposed between an upper surface of the clamp guide and the locking portion of the damping guide so that the clamp ring applies the distributed load to the substrate.

12. The substrate clamping device of claim 3, wherein the clamp guide includes a detachable groove with a screw portion under the damping groove, and
a screw coupling portion that is screw-coupled to the screw portion is provided on the outer circumferential surface of the damping shaft so that the damping member is detached from the clamp guide.

13. The substrate clamping device of claim 1, wherein the damping member is made of an elastic material.

14. The substrate clamping device of claim 1, further comprising: a measuring unit that measures a pressing force pressed by the driving unit; and
a control unit that controls a driving force of the driving unit according to the pressing force measured by the measuring unit.

15. A substrate treatment apparatus comprising: the substrate clamping device of claim 1; and
a treatment unit that performs a substrate treatment for the substrate that is supported on the supporting unit.
